(19) United States
(12) Patent Application Publication
(10) Pub. No.: US 2003/0064543 A1
(43) Pub. Date: Apr. 3, 2003

(54) Method and system for die transfer

(76) Inventors: Richard Lee Mahle, McKinney, TX (US); Randall Van Tekavec, McKinney, TX (US); Sreenivasan Kalyani Koduri, Plano, TX (US)

Correspondence Address: TEXAS INSTRUMENTS INCORPORATED, P O BOX 655474, M/S 3999, DALLAS, TX, 75265

(21) Appl. No.: 10/259,127

(22) Filed: Sep. 27, 2002

Related U.S. Application Data
(60) Provisional application No. 60/326,000, filed on Sep. 28, 2001.

(51) Int. Cl. H01L 21/48

(52) U.S. Cl. 438/106

(57) ABSTRACT

A method and system for die transfer is described. A die removably coupled to a die bonding element is provided. The die bonding element is coupled to a film frame. A carrier element having a pocket is also provided. At least one of the film frame and the carrier element are moved such that the die is aligned with the pocket. The selected die is pushed from the die bonding tape into the pocket.

### BACKGROUND OF THE INVENTION

As computers have grown increasingly important in today's society, the number of computers and other electronic devices has also increased. These computers and other electronic devices typically rely on one or more chips in order to perform their function. Thus, the production of the chips needed for the computers and other electronic devices has also increased.

### SUMMARY OF THE INVENTION

The present invention provides an improved method and system for die transfer.

In one embodiment of the present invention, a method and system for die transfer is provided. A die removably coupled to a die bonding element is provided. The die bonding element is coupled to a film frame. A carrier element having a pocket is also provided. At least one of the film frame and the carrier element are moved such that the die is aligned with the pocket. The selected die is pushed from the die bonding tape into the pocket.

The present invention provides various technical advantages. Various embodiments of the present invention may provide some, all or none of these technical advantages. One such technical advantages is the decreased number of alignments used to transfer a die from a die bonding element to a pocket on a carrier element. Decreasing the number of alignment steps allows increased speed of transferring dies from the die bonding element to the pockets on the carrier element.

Other technical advantages of the present invention will be readily apparent to one skilled in the art from the following figures, description, and claims.

### BRIEF DESCRIPTION OF THE DRAWINGS

The present invention is best understood from the detailed description which follows, taken in conjunction with the accompanying drawings, in which:

FIG. 1 is a block diagram illustrating a die transfer system according to one embodiment of the present invention; and

FIG. 2 is a flow chart illustrating a method of operation of the system of FIG. 1 according to one embodiment of the present invention.

### DETAILED DESCRIPTION OF THE INVENTION

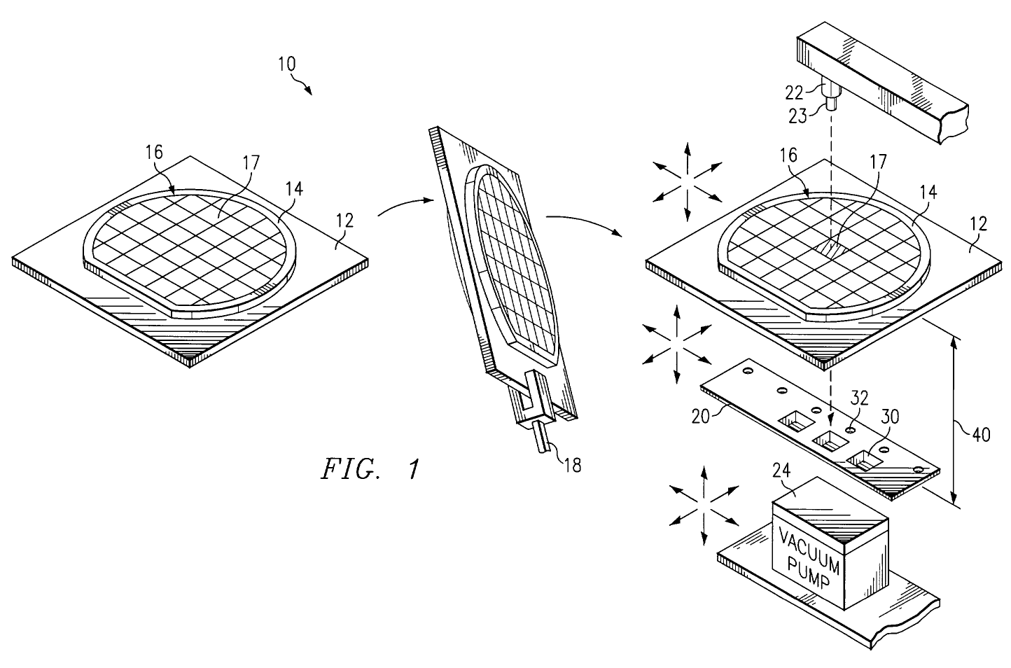

FIG. 1 is a diagram illustrating a die transfer system 10 according to one embodiment to the present invention. System 10 comprises a film frame 12, a die bonding element 14, a wafer 16, a flipping element 18, a carrier element 20, a pusher element 22, and an attraction element 24.

Film frame 12 comprises a device operable to hold wafer 16 in place while wafer 16 is sawn. More specifically, after circuitry has been etched onto various portions of wafer 16, wafer 16 includes one or more dies 17. Dies 17 are separated from each other when wafer 16 is cut up into the individual dies 17. For example, a chip saw, die saw or other wafer cutting device (not shown) may be used to saw wafer 16 into dies 17.

Die bonding element 14 comprises an adhesive substance capable of retaining sawn dies 17 against movement. For example, die bonding element 14 may comprise blue tape or other suitable die bonding tapes for holding dies 17.

Wafer 16 comprises a standard wafer operable to have dies 17 etched thereon. For example, wafer 16 may be from 100 to 300 m² in size. In general, wafer 16 may be of suitable size and shape, and of a suitable substance, such as silicon or gallium arsenide.

Die 17 comprises the etched portions of wafer 16. Dies 17 are separated from each other by a suitable cutting or sawing process after being etched. In one embodiment, dies 17 may include appropriate packaging, such as surface mount packaging. Dies 17 may be of a suitable size, such as between 0.3 mm² to 1 mm², but may be of other sizes. In general, die 17 may comprise a suitable chip, die and/or packaged device. For example, die 17 may represent an already packaged chip.

Flipping element 18 comprises a suitable device operable to invert frame 12. For example, flipping element 18 may comprise a mechanical arm operable to grip frame 12 and rotate frame 12 from a first position to a second position such that in the second position frame 12 is upside down from the first position. In general, a suitable device operable to flip frame 12 may be used as flipping element 18.

Carrier element 20 comprises a sealable tape having one or more pockets 30 for receiving dies 17. For example, carrier element 20 may comprise a standard carrier tape. In one embodiment, carrier element 20 may be moved in all three dimensions and comprises a linear tape having a plurality of pockets 30. For example, carrier element 20 may use a tractor feed mechanism using holes 32 in carrier element 20. Alternatively, carrier element 20 may comprise a waffle pack having multiple pockets 30 arranged in a non-linear arrangement, such as a circle or a square.

Pockets 30 comprise individual storage locations on carrier element 20 for holding individual dies 17. In one embodiment, pockets 30 are sized such that dies 17 are prevented from rotation within pockets 30. For example, pockets 30 may be only slightly larger than dies 17, so that dies 17 do not shift or rotate while carrier element 20 is being transported to a customer's location. More specifically, pockets 30 may be sized to be less than or equal to 50 microns larger than the size of die 17 in order to prevent rotation. Pockets 30 may be covered after receiving a die 17 for transport so that dies 17 do not fall out of pockets 30 during transport and movement.

Pusher element 22 comprises a fixed element operable to push a single die 17 from bonding tape 14 into pocket 30. More specifically, pusher element 22 comprises an end 23 for pushing dies 17 off of die bonding tape 14. In one embodiment, end 23 has a rounded tip so as to more effectively separate die 17 from bonding element 14. More specifically, pusher element 22 may comprise a needle having a rounded end. In general, end 23 comprises a suitable tip for pusher element 22 operable to separate a die 17 from die bonding element 14. Alternatively, pusher element 22 may be movable. For example, pusher element 22 may be movable to be aligned with die 17 and/or pocket 30.

Attraction element 24 comprises a device operable to attract dies 17 from carrier type 14 to pockets 30. For example, attraction element 24 may compress a vacuum pump operable to provide a suction force to pull die 17 from carrier element 14 as die 17 are being pushed by pusher element 22. In general, attraction device 24 may comprise a suitable device for attracting dies 17 to pockets 30 from die bonding element 14.

In operation, one or more dies 17 are etched on and then cut from wafer 16. Bonding element 14 retains sawn dies 17 in place and coupled to film frame 12. Flipper device 18 then inverts film frame 12 such that dies 17 are facing downward with die bonding element 14 holding dies 17 against the pull of gravity. Alternatively, film frame 12 and bonding element 14 may already have dies 17 facing downward toward carrier element 20 and not need to be inverted. For another alternative, system 10 may be inverted entirely such that pusher element 22 faces upwards, and carrier element 20 and attraction element 24 are above film frame 12. In this alternative, dies 17 may be pushed into pcokets 30 against the force of gravity.

Film frame 12 and carrier element 20 are then aligned such that a selected die 17 is underneath pusher element 22 and a selected pocket 30 is underneath the selected die 17. Film frame 12 and carrier element 20 may be moved in three dimensions as necessary to align the selected die 17 and the selected pocket 30. In one embodiment, a vision alignment system may be used. A distance 40 between film frame 12 and carrier element 20 may be maintained such that die 17 has a short distance to fall into pocket 30 while preventing interference between the movement of carrier element 20 and film frame 12. For example, distance 40 may be less than 1 mm, but may vary based on the size of the package associated with die 17. In general, distance 40 is set to be a suitable value based on the size of die 17 such that die 17 may freely fall into pcoket 30 while avoiding transfer problems such as friction.

Attraction device 24 may assist in pulling die 17 from carrier element 20 by, for example, generating a vacuum, or other pressure difference, such that die 17 is pulled toward pocket 30. Film frame 12, carrier element 20 and attraction device 24 may simultaneously move so that the selected die 17 contacts pusher element 22. In one embodiment, film frame 12, carrier element 20 and attraction device 24 may move upwards generally simultaneously such that the selected die 17 contacts end 23. Pusher element 22 and end 23 then displace die 17 into pocket 30. One advantage of system 10, in one embodiment, may be the capability to provide for a single transfer of die 17 from bonding tape 14 to pocket 30.

Film frame 12, carrier element 20 and attraction device 24 are then moved to realign a new die 17 with a new pocket 30 and the process is repeated.

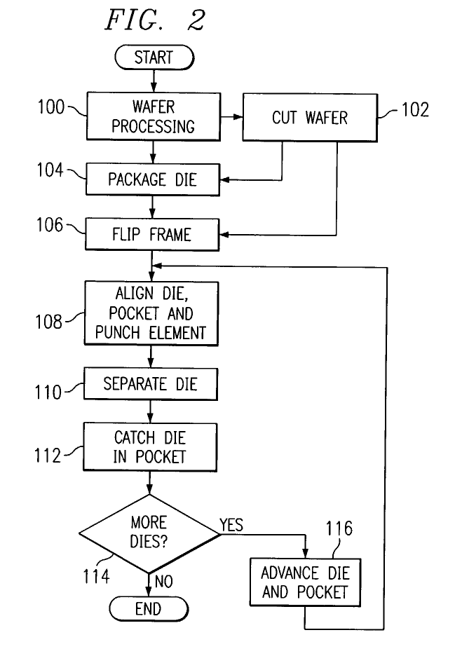

FIG. 2 is a flow chart illustrating a method of operation of system 10 according to one embodiment of the present invention. The method begins at step 100, where wafer 16 is processed in a suitable manner. For example, die 17 may be etched using a standard process.

In one embodiment, at step 102, wafer 16 is cut to separate dies 17 from each other. Then, at step 104, the cut dies 17 may be appropriately packaged. For example, die 17 may be packaged as a surface mount component, a chip-scale package, such as a chip-scale pacakge having conductive bumps directly attached to a die, or using other suitable die packaging formats.

Alternatively, the method may proceed from step 100 to step 104 where uncut dies 17 may be packaged and then to step 102 for cutting. For example, a hershey-bar style technique may coat wafer 16 in plastic and then cut wafer 16 into individual dies 17.

Proceeding to step 106, frame 12 is flipped by flipping element 18. Frame 12 is flipped so that dies 17 are now facing down and held by bonding element 14 against the force of gravity. Alternatively, frame 12 may already be oriented such that dies 17 are facing carrier element 20 such that bonding element 14 is not betweetn die 17 and pockets 30. In this alternate embodiment, inverting of frame 12 may not be needed and step 106 may be optional.

Next, at step 108, a selected die 17, a selected pocket 30 and attraction device 24 are aligned. For example, a standard vision alignment system may be used. Film frame 12, carrier tape 20 and attraction device 24 may then move substantially in unison such that the selected die 17 is pressed against end 23 of pusher element 22. Next, at step 110, die 17 separates from die bonding element 14 and falls into pocket 30 at step 112. Attraction device 24 may assist in removing die 17 from bonding tape 14 and pulling the separated die 17 into pocket 30. More specifically, as die 17 is pushed away from die bonding element 14 by end 23, gravity and attraction device 24 assist die 17 in falling into pocket 30.

Proceeding to decisional step 114, system 10 determines whether more dies 17 are to be disposed in pockets 30. If no further dies 17 are to be placed in pockets 30 then the NO branch of decisional step 114 leads to the end of the method. If additional dies 17 exist to be disposed in pockets 30, then the YES branch of decisional step 114 leads to step 116. At step 116, the next die 17 and next available pocket 30 are determined and the method returns to step 108 to align die 17, pocket 30 and attraction device 24.

One advantage of system 10 is that die 17 may be placed in pockets 30 using a single alignment step for a given die 17. More specifically, once die 17, end 23, and pocket 30 are aligned, die 17 is in position to be pushed into pocket 30. Traditional techniques of transferring dies 17 to pockets 30 may involve multiple alignment steps for each die 17. More specifically, traditional techniques had die 17 facing upwards on the film frame and separately removed individual dies from the die bonding tape. The die was then inverted and aligned with pocket 30 to be placed in pocket 30. The traditional technique involved two alignment steps, the first alignment step of aligning a flipping device with a die so as to avoid damage to other dies adjacent to the die to be flipped and to grab the die. The inverted die was then aligned again with the pocket on the carrier tape. The single alignment technique of system 10 allows for an increased speed of transfer of dies 17 to pockets 30 and a decrease in the number of alignments necessary to perform the transfer.

Other changes, substitutions, and alterations are also possible without departing from the spirit and scope of the present invention, as defined by the following claims.

What is claimed is:

1. A system for die packaging comprising:
a die removably coupled to a die bonding element, the die bonding element being coupled to a film frame;
a carrier element having a pocket, the pocket being operable to receive the die in response to the die separating from the die bonding element;
a pusher element operable to decouple the die from the die bonding element after the film frame has been inverted; and
wherein the carrier element, the pusher element and the film frame are operable to be moved such that the die is aligned with the pocket.

2. The system for die packaging according to claim 1 and further comprising:
an attraction element operable to pull the die from the die bonding element to the pocket by suction; and
wherein the film frame is operable to be inverted by a flipping element.

3. The system for die packaging according to claim 1, wherein the pusher element removes the die from the die bonding element with an end associated with the pusher element.

4. The system for die packaging according to claim 1, wherein the pusher element is in a fixed position and comprises a needle having a generally rounded point.

5. The system for die packaging according to claim 1, wherein the carrier element comprises a carrier tape.

6. The system for die packaging according to claim 1, wherein the die bonding element comprises a die bonding tape.

7. The system for die packaging according to claim 1, wherein the inverted film frame comprises the film frame in an upside down position wherein the die is retained against the force of gravity by the die bonding element.

8. The system for die packaging according to claim 1 and further comprising a plurality of the dies and a plurality of the pockets.

9. A method for die packaging comprising:
providing a plurality of separated dies removably coupled to a die bonding element, the die bonding element being coupled to a film frame;
providing a carrier element having a plurality of pockets;
moving at least one of the film frame and the carrier element such that a selected one of the dies is aligned with a selected one of the pockets;
pushing the selected die from the die bonding element into the pocket.

10. The method for die packaging according to claim 9 and further comprising pulling the selected sawn die from the die bonding element to the pocket by suction.

11. The method for die packaging according to claim 9, wherein moving the film frame comprises:
moving the carrier element such that the selected sawn die is aligned with the selected pocket; and
moving the film frame such that the selected sawn die is aligned with a pusher element.

12. The method for die packaging according to claim 11, wherein pushing the selected die comprises moving the film frame and the carrier element such that an end of the pusher element separates the selected die from the die bonding element.

13. The method for die packaging according to claim 11, wherein the pusher element is at a fixed location and comprises a needle having a generally rounded point.

14. The method for die packaging according to claim 9, wherein the carrier element comprises a carrier tape.

15. The method for die packaging according to claim 9, wherein the die bonding element comprises a die bonding tape.

16. The method for die packaging according to claim 9 and further comprising inverting the film frame, wherein inverting the film frame comprises turning the frame upside down.

17. A method for die packaging comprising:
means for providing a plurality of separated dies removably coupled to a die bonding element, the die bonding element being coupled to a film frame;
means for providing a carrier element having a plurality of pockets;
means for moving at least one of the film frame and the carrier element such that a selected one of the dies is aligned with a selected one of the pockets;
means for pushing the selected die from the die bonding element into the pocket.

18. The method for die packaging according to claim 17 and further comprising means for inverting the film frame.
